(19) United States
(12) Patent Application Publication
(10) Pub. No.: US 2013/0200506 A1
(43) Pub. Date: Aug. 8, 2013

(54) METHOD OF PREVENTING EPOXY BLEED OUT OF LEAD FRAME AND LEAD FRAME MANUFACTURED BY USING THE SAME

(71) Applicant: Samsung Techwin Co., Ltd., Changwon-city (KR)

(72) Inventor: Sang-yearl PARK, Changwon-city (KR)

(73) Assignee: SAMSUNG TECHWIN CO., LTD., Changwon-city (KR)

(21) Appl. No.: 13/686,168

(22) Filed: Nov. 27, 2012

(30) Foreign Application Priority Data
Feb. 3, 2012 (KR) 2012-0011049

(51) Int. Cl. H01L 23/00

(52) U.S. Cl. CPC H01L 24/50
USPC 257/676; 156/242; 156/73.1

(57) ABSTRACT

The epoxy bleed out prevention method including: providing a lead frame that is manufactured through a shaping process which forms a die pad and a plurality of leads by using a conductive raw material, a pre-plating process performed on the shaped conductive raw material, and a tape attaching process; and performing a bleed out prevention process which prevents an epoxy bleed out of a die bonding epoxy-based resin applied on the die pad after the tape attaching process.

### CROSS-REFERENCE TO RELATED PATENT APPLICATION

This application claims priority from Korean Patent Application No. 10-2012-0011049, filed on Feb. 3, 2012, in the Korean Intellectual Property Office, the disclosure of which is incorporated herein by reference in its entirety.

### BACKGROUND

1. Field

Methods consistent with exemplary embodiments relate to preventing an epoxy bleed out of a lead frame.

2. Description of the Related Art

A lead frame or a printed wiring plate for a semiconductor package undergoes assembly processes for forming a semiconductor package by connecting a semiconductor chip to an external circuit, and the assembly processes generally include a die bonding process, a wire bonding process, and a molding process. Among the assembly processes, the die bonding process is a process of bonding and fixing a die pad such as a lead frame to a semiconductor chip using an adhesive, wherein an epoxy-based resin is mainly used as the adhesive.

When performing the die bonding process using an epoxy-based resin, an epoxy bleed out phenomenon, which is exudation of resin or additives, occurs due to 1) a contaminated surface from organic materials such as a discolor prevention agent and a sealing agent, 2) a surface roughness of a bonding surface plated with gold, silver, or palladium, and 3) physical properties of the used epoxy-based resin. The epoxy bleed out may reduce a strength of the die bonding operation or may cause defects in the following wire bonding process.

The surface roughness of the bonding surface is caused by a development of a pre-plated frame (PPF) lead frame, in which a predetermined roughness is applied to a plating layer to improve an adhesive force between the semiconductor chip and the die pad during the die bonding process, to improve a bonding property during a wire bonding process, and to manufacture a semiconductor package having an excellent delamination quality and molding resin adhesive property under inferior temperature and humidity conditions. Thus, a surface of a general PPF lead frame, on which a semiconductor chip is mounted and a wire bonding operation is performed, has a predetermined surface roughness, as disclosed in Korean Registered Patent No. 0819800. Here, the PPF lead frame allows a lead plating process in semiconductor post-processes to be omitted, a lead of an uppermost layer of a semiconductor package that is exposed out of a mold may be formed of gold or gold alloy so as to conveniently perform a mounting process of a package by soldering the package on a printed circuit board and to prevent environmental contamination. By applying the predetermined surface roughness, a semiconductor package having an excellent adhesive property during the mounting process of the semiconductor chip may be manufactured. However, the epoxy bleed out phenomenon becomes severe due to a capillary phenomenon during the die bonding process performed on the surface of the lead frame, thereby increasing a specific surface area. Accordingly, the strength of the die bonding may decrease and the wire bonding process or the molding may be negatively influenced. In the related art, in order to prevent the epoxy bleed out caused by the surface roughness, the surface roughness is reduced to restrain the capillary phenomenon or the surface is cleaned to remove contamination. However, the surface roughness of the bonding surface affects the die bonding strength or an image recognition performance of an assembly machine, and thus, there is a limitation in reducing the surface roughness. Also, the surface cleaning may damage a discolor prevention process or a sealing process.

Also, in recent developments of a small thickness of a semiconductor package, an epoxy-based resin for the die bonding having low stress, low elasticity, and low viscosity, which is likely to include a component that is easily exuded, have been frequently used to prevent warpage of a substrate. Accordingly, the epoxy bleed out phenomenon becomes severe. To address this problem, Korean Registered Patent No. 0953008 suggests an epoxy bleed out prevention agent having a fluorohydrocarbon group that may effectively prevent the epoxy bleed out phenomenon. That is, it becomes more difficult to prevent the epoxy bleed out phenomenon, in addition to a requirement of the lead frame having a surface roughness for manufacturing a package with high reliability.

Meanwhile, there are some cases where manufacturing processes of the lead frame include a tape attaching process. For example, a product group such as a quad flat package (QFP) that uses a lead lock tape in order to address the problem of handling characteristics or package reliability during the semiconductor manufacturing processes by fixing locations of leads when an internal lead has a long length or a large number of internal leads. A QFN product group, in which a back side tape is used to prevent a mold flash in order to prevent a molding resin from leaking during the molding process, may be another example. The processes of manufacturing the lead frame including the tape attaching process are mainly performed in a reel-to-reel continuous manner in order to improve productivity, and may include a shaping process using an etching or a stamping operation, a wet process including a plating such as in the PPF and an epoxy bleed out prevention process, and post-processes such as a taping, a down-set, and a cut-off operation performed in a dry environment such as in a clean room. That is, the epoxy bleed out prevention process is performed during processes of manufacturing the lead frame. Generally the epoxy bleed out process is performed as a wet type process, for example, soaking a lead frame, after the plating is completed, in a tub containing an epoxy bleed out prevention agent at the end of the plating process under a wet environment, such as the PPF, or spraying the epoxy bleed out prevention liquid onto the lead frame, and cleaning and drying the lead frame. In addition, if a taping process is necessary, the taping process is performed during the post-processes performed under a dry environment, after finishing the plating and the epoxy bleed out prevention processes under a wet environment.

As described above, the related art epoxy bleed out prevention process is performed as a wet type process on entire surfaces including opposite surfaces of the lead frame that is processed as a penetration with the plating process, and thus, a die pad that substantially requires the epoxy bleed out prevention function of the lead frame, on which the chip is mounted, may not be selectively processed. In addition, the epoxy bleed out prevention agent is generally coated and forms an organic layer on the lead frame so as to reduce a surface energy of the lead frame to be less than that of the die bonding epoxy resin, thereby realizing the epoxy bleed out prevention function. However, it is difficult for the epoxy bleed out prevention agent to attach to a different kind of material such as tape. Thus, when the taped region is processed by the epoxy bleed out prevention agent, an adhesive force is reduced, thereby causing a lot of problems during the post manufacturing processes. The above-described problem becomes severe when the epoxy bleed out prevention agent having a strong concentration is applied to a lead frame having a predetermined surface roughness for achieving high reliability.

Thus, a process of maintaining an excellent tape adhesive force is necessary while maintaining the epoxy bleed out prevention function when the tape attaching process is included in the manufacturing processes of the lead frame.

### SUMMARY

One or more exemplary embodiments provide a method of preventing epoxy bleed out of a lead frame, which is capable of preventing reduction of a tape adhesive force while maintaining an epoxy bleed out prevention function, even with processing conditions that may reduce the adhesive force of the tape, such as a pre-plating process applying a predetermined surface roughness and using of a die bonding epoxy-based resin having low stress in processes of manufacturing the lead frame including the tape attaching process.

According to an aspect of an exemplary embodiment, there is provided an epoxy bleed out prevention method including: providing a lead frame manufactured through a shaping process which forms a die pad and a plurality of leads by using a conductive raw material, a pre-plating process performed on the shaped conductive raw material, and a tape attaching process; and performing a bleed out prevention process which prevents an epoxy bleed out of a die bonding epoxy-based resin applied on the die pad after the tape attaching process.

The pre-plating process may comprise applying a surface roughness.

A tape used in the tape attaching process may be a lead lock tape which fixes a plurality of leads, or a back side tape which prevents a mold flash.

The die bonding epoxy-based resin may contain a component which reduces stress, elasticity, or viscosity.

The performing of the bleed out prevention process may include applying a liquid-type bleed out prevention agent only on the die pad under a dry environment.

The dry environment may be the same as an environment where the tape attaching process is performed.

A dry-type spray module may spray the liquid-type bleed out prevention agent.

The dry-type spray module may be an ultrasonic spray module.

The liquid-type bleed out prevention agent may comprise water or an organic solvent.

The organic solvent may include at least one solvent selected from the group consisting of methanol, ethanol, isopropanol, acetone, and methylethylketone.

The performing of the bleed out prevention process may be applied on one surface of the die pad.

The performing of the epoxy bleed out prevention method may further include a surface treatment process using an atmospheric pressure plasma discharge, between the tape attaching process and the performing of the bleed out prevention process.

The conductive raw material may be a reel-type conductive material, a tape used in the tape attaching process may be a continuous reel-type tape, and the method may further include performing a cut-off process for cutting the lead frame of a reel type, on which the epoxy bleed out prevention process is performed, into lead frame strips.

The cut-off process the tape attaching process and the epoxy bleed out prevention process may be performed under the dry environment.

The conductive raw material may be reeled, and the method may further include performing a cut-off process which cuts the lead frame of a reel type into lead frame strips, between the shaping process and the pre-plating process, wherein the tape attaching process is performed in an individual strip taping method.

According to an aspect of another exemplary embodiment, there is provided a lead frame manufactured by the performing of the epoxy bleed out prevention method.

According to an aspect of another exemplary embodiment, there is provided an epoxy bleed out prevention method for a lead frame including a die pad and a plurality of leads, the method including: attaching a tape to the lead frame; and performing a bleed out prevention process which prevents an epoxy bleed out of a die bonding epoxy-based resin applied on the die pad, after the attaching the tape to the lead frame.

The performing of the bleed out prevention process may comprise applying a bleed out prevention agent only on the die pad under a dry environment.

According to an aspect of another exemplary embodiment, there is provided an epoxy bleed out prevention method for a lead frame including a die pad and a plurality of leads, the method including: providing a conductive raw material; shaping the lead frame including the die pad and the plurality of leads using the conductive raw material; performing a pre-plating process; attaching a tape onto the lead frame; performing a bleed out prevention process; and cutting the lead frame into strip type lead frames. The attaching of the tape, the performing of the bleed out prevention process and the cutting of the lead frame are performed under a same condition.

The performing the bleed out prevention process is performed after the attaching of the tape, and the attaching of the tape, the performing of the bleed out prevention process and the cutting of the lead frame are performed under a dry condition.

### BRIEF DESCRIPTION OF THE DRAWINGS

The above and other aspects will become more apparent by describing in detail exemplary embodiments thereof with reference to the attached drawings of which:

FIG. 1 is a flowchart illustrating a method of preventing an epoxy bleed out of a lead frame according to an exemplary embodiment;

FIG. 2 is a diagram showing an exemplary embodiment of a lead frame where a lead lock tape is attached;

FIG. 3 is a diagram showing an exemplary embodiment of a lead frame where a back side tape is attached;

FIG. 4 is a diagram showing an ultrasound spray module according to an exemplary embodiment;

FIG. 5 is a flowchart illustrating another method of preventing an epoxy bleed out of a lead frame, according to another exemplary embodiment;

FIG. 6 is a flowchart illustrating yet another method of preventing an epoxy bleed out of a lead frame, according to another exemplary embodiment;

FIG. 7 is a diagram illustrating a method of evaluating a degree of an epoxy bleed out; and

FIG. 8 is a diagram illustrating a method of evaluating a tape adhesive force.

### DETAILED DESCRIPTION

Hereinafter, exemplary embodiments will now be described more fully with reference to the accompanying drawings. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

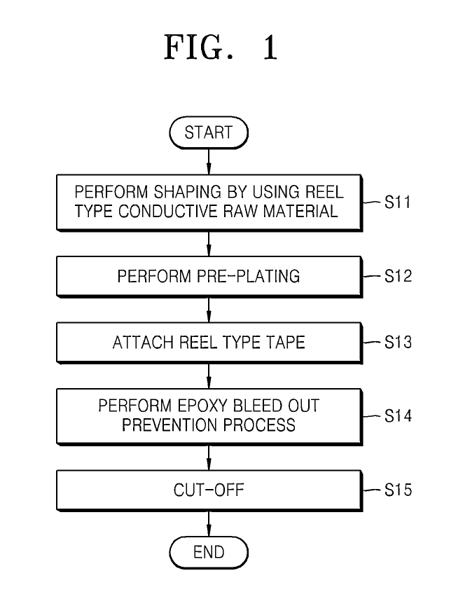

FIG. 1 is a flowchart illustrating a method of preventing an epoxy bleed out of a lead frame according to an exemplary embodiment.

Referring to FIG. 1, the method of preventing the epoxy bleed out of a lead frame according to the exemplary embodiment includes a shaping process (S11) using a reel of conductive raw material, a pre-plating process (S12), a reel-type tape attaching process (S13), an epoxy bleed out prevention process (S14), and a cut-off process (S15). Hereinafter, each of the processes will be described in detail.

First, the shaping process (S11) is a process of manufacturing a basic shape of a lead frame including a die pad and a plurality of leads by using a conductive raw material such as copper or a copper alloy fabricated by mixing nickel, silicon, and phosphor as a raw material of the lead frame. The die pad is disposed on a center portion of the lead frame, and a semiconductor chip is mounted on the die pad during post packaging processes. The plurality of leads includes an inner lead and an outer lead. The inner lead may be electrically connected to the semiconductor chip via a bonding wire, and the outer lead extends in a length direction of the inner lead to be electrically connected to an external circuit such as a printed circuit board.

The shaping process may be performed by using a well-known method, for example, by patterning the die pad and the leads by using a chemical method such as an etching method or a mechanical method such as a stamping or punching operation.

Next, the pre-plating process (S12) is a process of applying a material having an excellent soldering wet property onto the conductive raw material in advance before performing a semiconductor packaging process, so that a soldering process in the post semiconductor processes may be omitted. In addition, a plating layer may be formed by electric current flowing in the shaped raw material by using a plating solution. The plating layer formed through the pre-plating process may sequentially form a nickel layer and a palladium layer on an upper portion of a base metal layer mainly containing, for example, copper, and a gold plating layer may be formed as the uppermost layer in order to prevent degradation of physical properties caused due to a palladium compound that is oxidized by heat generated during the semiconductor assembly processes. A plating layer of gold and palladium alloy may be formed in order to prevent degradation of an adhesive force with a molding resin due to the pure gold plating layer formed at the uppermost layer. That is, the plating layer may be selectively formed according to an objective of manufacturing the lead frame having desired physical properties.

Here, in order to maintain a high adhesive force between the molding resin and the lead frame under a harsh environment where temperature and humidity are very high when manufacturing a semiconductor package, a surface roughness may be applied to the plating layer. For example, as disclosed in Korean Patent Registration Publication No. 0819800, plating layers of Ni/rougher Ni/Pd/Au are formed on the base metal layer as the plating layers to be rough, so that the adhesive force between the molding resin and the lead frame may be improved. Here, as described above, when a taping process is necessary, a stronger epoxy bleed out prevention agent has to be used due to the surface roughness, and an adhesive force of the tape may be further reduced due to the wet environment. However, as will be described below, the epoxy bleed out prevention agent of the exemplary embodiment is processed only on the die pad right after the taping process so as not to reduce the adhesive force of the tape, thus maintaining an excellent adhesive force between the molding resin and the lead frame without causing side effects due to the taping process.

Meanwhile, in order to improve the attaching reliability between a bonding wire and an inner lead when mounting a semiconductor chip after the pre-plating process, a plating process for plating silver (Ag) on an inner lead portion that is wire bonded may be further performed.

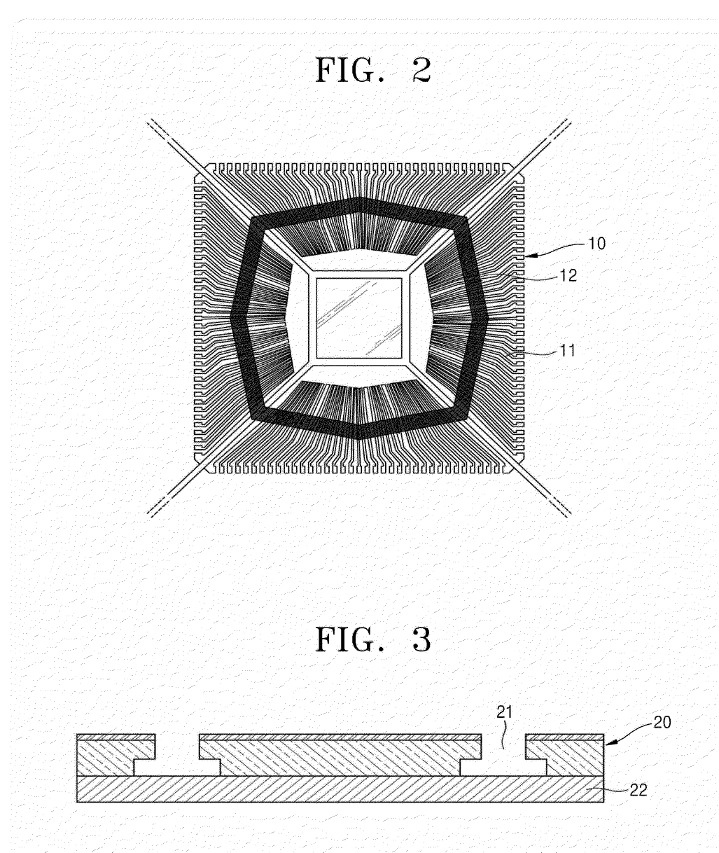

Next, the tape attaching process (S13) is performed depending on demand when manufacturing the lead frame. However, since the exemplary embodiment address problems such as a degradation of the tape adhesive force and a selective process of the die pad, which is generated during the taping process and the epoxy bleed out prevention process that will be described below, the present exemplary embodiment includes the tape attaching process (S13). Exemplary embodiments of the tape attaching process (S13) may include an attaching process of a lead lock tape 12 (refer to FIG. 2) to improve handling characteristic or to address problems of package reliability during assembly of the semiconductor package by fixing locations of the leads 11 when the inner lead of the lead frame 10 is long or has a large number of inner leads, or an attaching process of a back side tape 22 (refer to FIG. 3) that prevents a mold flash, which is leaking of the molding resin during the molding process. The back side tape 22 also covers the outer lead that is exposed when the package is mounted on a printed circuit board.

In the exemplary embodiment, a reel-type conductive raw material is used, and the tape attaching process is performed in a continuous reel-type taping under a dry environment, unlike the pre-plating process that is performed in a wet environment. Therefore, in an another exemplary embodiment that is described below, in which a reel-type lead frame is cut into strip-type lead frames and a strip taping process is performed individually, the manufacturing processes of the lead frame are performed in dry-wet-dry environments sequentially, thereby separating the process performed under a dry environment into two parts. However, in the present exemplary embodiment, the processes are performed in wet-dry environments, and thus, it is advantageous in view of processing efficiency and manufacturing costs.

The tape may include a first layer and a second layer. The first layer may be formed of a polyimide material having no adhesive force, and the second layer may be formed of a material in which an epoxy resin having an adhesive force and rubber are mixed. Therefore, the second layer of the tape is attached onto the raw material so as to fix the leads or prevent a mold flash.

Next, the epoxy bleed out prevention process (S14) prevents the epoxy bleed out phenomenon, which is exudation of the epoxy resin for die bonding. The epoxy resin is applied on the die pad when manufacturing the semiconductor package, so as to prevent degradation of the die bonding strength and the occurrence of defects during a wire bonding process. In the epoxy bleed out prevention process (S14), an organic layer is formed onto the die pad so as to reduce a surface energy of the die pad.

As described above, when an epoxy bleed out prevention agent having a stronger epoxy bleed out prevention function is used in a wet environment like in the related art to prevent severe generation of the epoxy bleed out due to usage of the die bonding epoxy-based resin having low stress, low elasticity, and low viscosity, which is likely to include contents that are easily exuded, the adhesive force of the tape is greatly reduced when the taping process is performed after the epoxy bleed out prevention process. According to the exemplary embodiment, the epoxy bleed out prevention agent is only applied on the die pad right after the taping process in order to prevent the degradation of the adhesive force of the tape, and accordingly, the adhesive force may be maintained between the molding resin and the lead frame without generating side effects due to the taping process.

The die bonding epoxy-based resin having low stress, low elasticity, and low viscosity may be, for example, a low stress epoxy-based resin, in which a silicon-based or olefin rubber-based stress reducing agent is included in the epoxy-based resin, a low elasticity epoxy-based resin, in which an epoxy modified polysiloxane, amine modified polysiloxane, polysiloxane-epoxy resin copolymer, and silicon rubber particles are included in the epoxy resin, or a low viscosity epoxy-based resin, in which acid anhydride is included in the epoxy resin.

In the exemplary embodiment, the epoxy bleed out prevention process may be applied only on the die pad under a dry environment, and it may be desirable that the epoxy bleed out prevention process is applied on one surface of the die pad, and a semiconductor chip is mounted on the one surface of the die pad in post packaging processes. The dry environment is the same environment as the dry environment under which the tape attaching process is performed. The epoxy bleed out prevention process may be performed right after the tape attaching process with a taping equipment usable in a dry environment. Therefore, the degradation of the tape adhesive force due to the applying of the epoxy bleed out prevention agent throughout the entire surfaces of the lead frame due to the wet environment such as a soaking environment may be prevented, and the tape attaching process and the epoxy bleed out prevention process may be continuously performed in the same dry environment, thereby improving a process efficiency.

Hereinafter, a case where the epoxy bleed out prevention process is performed in a wet environment according to the related art and not in a dry environment under which the tape attaching process is performed, may be considered. In this case, the epoxy bleed out prevention process may be performed after the tape attaching process in order to prevent the degradation of the tape adhesive force; however, the taping is performed in a wet deposition method on a penetration 21 of the lead frame 20 and a side surface of the raw material is blocked by the back side tape 22 so that it is difficult to drain the solution and perform drying (refer to FIG. 3). In addition, an additional wet process is performed so as to cause rising of manufacturing costs, and the manufacturing processes are performed under a wet environment where the plating process is performed, a dry environment where the tape attaching process is performed, a wet environment where the epoxy bleed out prevention process is performed, and a dry environment where the cut-off process is performed, and thus, a configuration of the processes is not desirable.

The epoxy bleed out prevention process of the exemplary embodiment may be performed in a spray coating process by using a liquid epoxy bleed out prevention agent only on the die pad under a dry environment.

The liquid epoxy bleed out prevention agent may include an organic material containing well-known epoxy bleed out prevention components, for example, carboxylic acid or thiol. The epoxy bleed out prevention agent may have any kind of physical property provided that it can be sprayed onto a part of the lead frame, or the die pad, in a mixture solution state. However, the epoxy bleed out prevention agent may be highly volatile and may be dissolved in a solvent to a predetermined concentration.

The solvent may be water or an organic solvent, and the organic solvent may be, for example, alcohol such as methanol, ethanol, and isopropanol, or ketone such as acetone and methylethyl ketone. Also, the solvent may be isopropanol that does not cause stains after being dried in the dry environment and be easily adhered on a surface of a substrate such as the lead frame. When the water is used as the solvent and the epoxy bleed out prevention component is difficult to be dissolved in the water, an organic solvent such as the alcohol and ketone may be added, and the added amount is an amount required to dissolve the epoxy bleed out prevention component in the water about 0.01 to 20 weight % of a total weight of the solvent, and preferably 0.1 to 5 weight %. In addition, an epoxy bleed out prevention agent including fluorohydrocarbon group having a stronger epoxy bleed out prevention function may be used.

The epoxy bleed out prevention component may be contained 0.1 to 10 weight %, and preferably 0.2 to 2 weight %, and more preferably 0.3 to 1 weight %, with respect to the total weight of the epoxy out prevention agent. When the epoxy bleed out prevention component is contained less than 0.1 weight %, the epoxy bleed out prevention function is not sufficient, and when the epoxy bleed out prevention component is contained higher than 10 weight %, more effect than it is obtained from that content may not be expected.

In addition, a discolor prevention agent of a surface of a plating surface or a discolor prevention agent of a surface of the conductive material and a sealing agent may be contained with the epoxy bleed out prevention component, and accordingly, the discolor prevention effect and the sealing effect may be simultaneously shown.

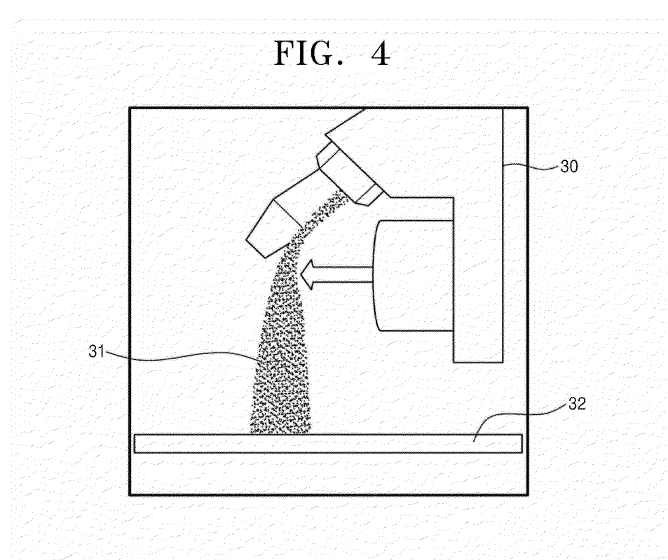

The spray module may be a module 30 to which an ultrasonic spray method is applied, as shown in FIG. 4. The ultrasonic spray method is advantageous in view that a coating liquid 31 that contains particles obtained by ultrasound easily are adhered on the surface of the conductive material 32, and even if the coating liquid 31 is coated on the portion where the tape is attached, preventing degradation of the tape adhesive force can be easily performed.

Meanwhile, an atmospheric plasma discharge process may be further performed as a pre-process in order to remove surface contamination of the taped lead frame and improve a surface adhesion of the epoxy bleed out prevention agent that will be applied, before the epoxy bleed out prevention process. The atmospheric pressure plasma discharge may be selectively performed only on the die pad region by using a mask. The plasma process may be performed by using fluoroform gas, for example, by generating discharge of the fluoroform gas by applying an electric current of 50 mA. Also, an oxygen gas discharge may be generated before generating the fluoroform gas discharge in order to easily make the plasma discharge and improve a reliability of the processed surface.

Next, the cut-off process (S15), which is a process of cutting the reel-type lead frame, on which the tape is attached in a continuous taping method and the epoxy bleed out prevention process are performed, forms a final product shape of a strip type (reel-to-strip). The cut-off process may be performed under a dry environment by using a well-known cut-off equipment.

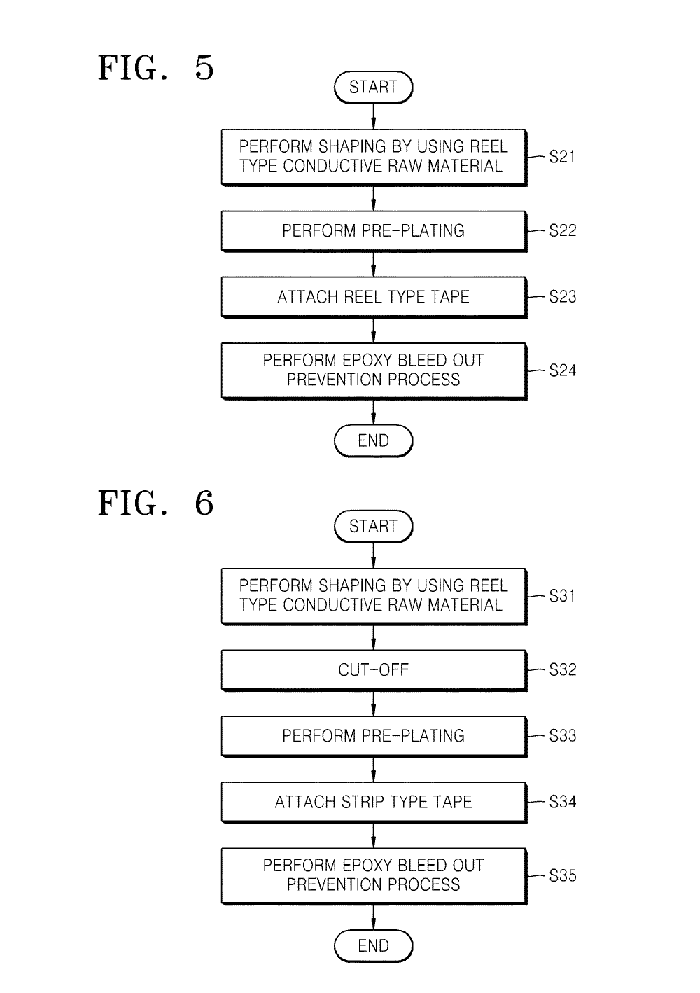

FIG. 5 is a flowchart illustrating an epoxy bleed out prevention method of a lead frame according to another exemplary embodiment.

Referring to FIG. 5, the epoxy bleed out prevention method of the lead frame, according to the present exemplary embodiment, includes a shaping process (S21) using a reel of conductive raw material, like in the previous exemplary embodiment, a pre-plating process (S22), a reel-type tape attaching process (S23), and an epoxy bleed out prevention process (S24). An additional cut-off process is omitted in the present exemplary embodiment.

The epoxy bleed out prevention method of the lead frame, according to the present exemplary embodiment, includes a retrieving process of the final lead frame product to a reel (reel-to-reel manner) after the epoxy bleed out process, without performing the cut-off process.

FIG. 6 is a flowchart illustrating an epoxy bleed out prevention method of a lead frame, according to yet another exemplary embodiment.

Referring to FIG. 6, the epoxy bleed out prevention method of the lead frame, according to the present exemplary embodiment, includes a shaping process (S31) using a reel of conductive raw material, a cut-off process (S32), a pre-plating process (S33), a strip-type tape attaching process (S34), and an epoxy bleed out prevention process (S35). Hereinafter, a configuration that is different from the previous exemplary embodiments will be described.

According to the epoxy bleed out prevention method of the lead frame, according to the present exemplary embodiment, the reel of shaped conductive raw material is cut under a dry environment, before performing of the pre-plating process performed under a wet environment, unlike the previous exemplary embodiments, to fabricate the lead frame with a strip shape. Consequently, the tape attaching process is performed in an individual strip taping method. After that, the epoxy bleed out prevention process is performed, and the final product is fabricated as a strip-type lead frame (strip type).

According to the method of the present embodiment, the manufacturing of a lead frame is performed under dry-wet-dry environments, thereby increasing the number of the processes and manufacturing costs. However, when the epoxy bleed out process is performed after the tape attaching process under the same dry environment, the same effects as those of the previous embodiment may be obtained.

### Experimental Example

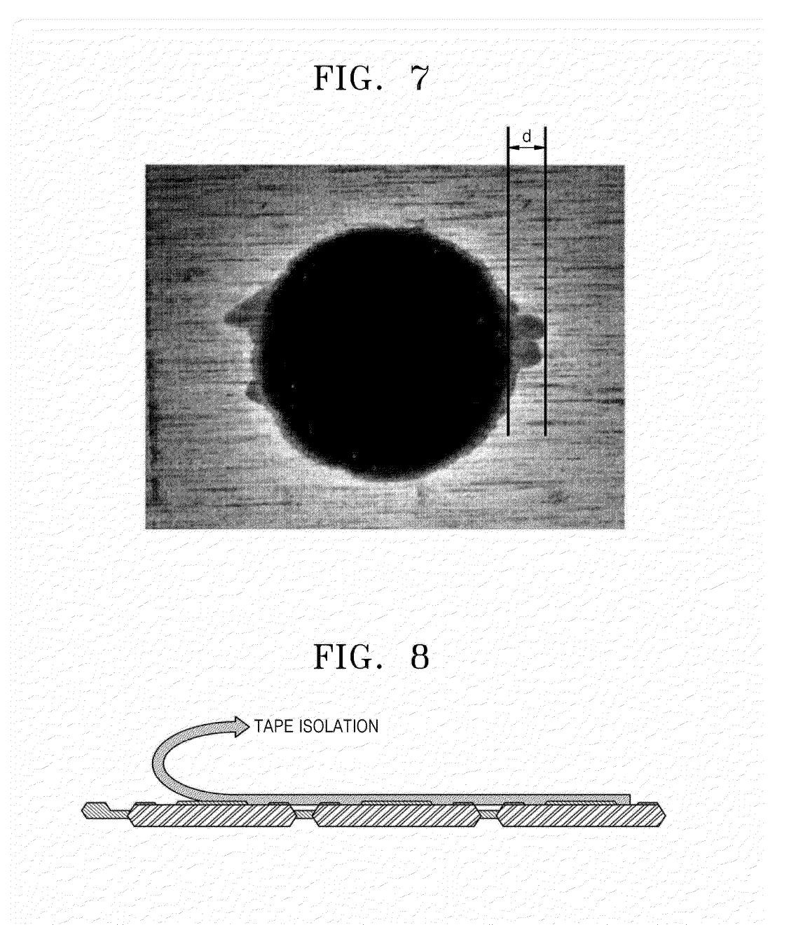

According to the epoxy bleed out prevention method of the first exemplary embodiment, on a QFN material on which a back side tape (A-T5, Tomoegawa, Inc.), wherein a surface roughness is applied and the uppermost surface of the QFN material is plated with gold-palladium alloy, an epoxy bleed out prevention agent (a solution in which Thiol having 12 or more carbon atoms at a main chain portion is contained by 0.3 weight % in isopropanol solvent) was applied by using an ultrasonic spray module under a dry environment. After that, a low stress epoxy (Ag epoxy) material (Ablebond 8200T, Ablestick Inc.) is dotted on a chip mounting surface, and then an epoxy bleed out degree and an attaching force to the back side tape were measured. As shown in FIG. 7, the epoxy bleed out degree was evaluated by measuring a vertical length d of the epoxy bleed out portion, and the adhesive force was evaluated by an isolation test, as shown in FIG. 8. As a result, the epoxy bleed out degree is about 5 μm, which shows an excellent epoxy bleed out prevention effect, and the tape adhesive force is about 0.3 gf/cm or greater, which shows an excellent adhesive force.

According to the measuring result, the method of the exemplary embodiments may provide a lead frame having an excellent epoxy bleed out prevention function and an excellent tape adhesive force, whereas it is difficult to perform the tape attaching process when the epoxy bleed out process is performed under a wet environment according to the related art.

According to the one or more exemplary embodiments, the epoxy bleed out prevention process is performed after the tape attaching process when manufacturing a lead frame including a tape attaching operation, and thus, the epoxy bleed out function may be maintained, and at the same time, the degradation of the tape adhesive force due to a wet environment in which the plating process is performed may be prevented.

Also, an epoxy bleed out prevention agent is only sprayed on a die pad on which a semiconductor chip is attached under a dry environment, thus preventing the degradation of the tape adhesive force and reducing manufacturing costs.

While the inventive concept has been particularly shown and described with reference to exemplary embodiments thereof, it will be understood by one of ordinary skill in the art that various changes in form and details may be made therein without departing from the spirit and scope of the inventive concept as defined by the following claims.

What is claimed is:

1. An epoxy bleed out prevention method comprising:
providing a lead frame manufactured through a shaping process which forms a die pad and a plurality of leads by using a conductive raw material, a pre-plating process performed on the shaped conductive raw material, and a tape attaching process; and
performing a bleed out prevention process which prevents an epoxy bleed out of a die bonding epoxy-based resin applied on the die pad after the tape attaching process.

2. The method of claim 1, wherein the pre-plating process comprises applying a surface roughness.

3. The method of claim 1, wherein a tape used in the tape attaching process comprises a lead lock tape which fixes a plurality of leads, or a back side tape which prevents a mold flash.

4. The method of claim 1, wherein the die bonding epoxy-based resin comprises a component which reduces stress, elasticity, or viscosity.

5. The method of claim 1, wherein the performing of the bleed out prevention process comprises applying a liquid-type bleed out prevention agent only on the die pad under a dry environment.

6. The method of claim 5, wherein the dry environment is the same as an environment where the tape attaching process is performed.

7. The method of claim 5, wherein a dry-type spray module sprays the liquid-type bleed out prevention agent.

8. The method of claim 7, wherein the dry-type spray module comprises an ultrasonic spray module.

9. The method of claim 5, wherein the liquid-type bleed out prevention agent comprises water or an organic solvent

10. The method of claim 9, wherein the organic solvent comprises at least one solvent selected from the group consisting of methanol, ethanol, isopropanol, acetone, and methylethylketone.

11. The method of claim 1, wherein the performing of the bleed out prevention process is applied on one surface of the die pad.

12. The method of claim 1, further comprising performing a surface treatment process using an atmospheric pressure plasma discharge, between the tape attaching process and the performing of the bleed out prevention process.

13. The method of claim 1, wherein the conductive raw material comprises a reel-type conductive raw material, a tape used in the tape attaching process comprises a continuous reel-type tape, and the method further comprises performing a cut-off process which cuts a reel type lead frame , on which the epoxy bleed out prevention process is performed, into lead frame strips.

14. The method of claim 13, wherein the cut-off process, the tape attaching process and the epoxy bleed out prevention process are performed under a dry environment.

15. The method of claim 1, wherein the conductive raw material is reeled, and the method further comprises performing a cut-off process which cuts the lead frame of a reel type into lead frame strips between the shaping process and the pre-plating process,
wherein the tape attaching process is performed in an individual strip taping method.

16. A lead frame manufactured by the performing of the epoxy bleed out prevention method according to claim 1.

17. An epoxy bleed out prevention method for a lead frame including a die pad and a plurality of leads, the method comprising:
attaching a tape to the lead frame; and
performing a bleed out prevention process which prevents an epoxy bleed out of a die bonding epoxy-based resin applied on the die pad after the attaching the tape to the lead frame.

18. The method of claim 17, wherein the performing of the bleed out prevention process comprises applying a bleed out prevention agent only on the die pad under a dry environment.

19. An epoxy bleed out prevention method for a lead frame including a die pad and a plurality of leads, the method comprising:
providing a conductive raw material;
shaping the lead frame including the die pad and the plurality of leads using the conductive raw material;
performing a pre-plating process;
attaching a tape onto the lead frame;
performing a bleed out prevention process; and
cutting the lead frame into strip type lead frames,
wherein the attaching of the tape, the performing of the bleed out prevention process and the cutting of the lead frame are performed under a same condition.

20. The method of claim 19, wherein the performing the bleed out prevention process is performed after the attaching of the tape, and
wherein the attaching of the tape, the performing of the bleed out prevention process and the cutting of the lead frame are performed under a dry condition.
